(19) United States
(12) Patent Application Publication
(10) Pub. No.: US 2025/0154652 A1
(43) Pub. Date: May 15, 2025

(54) LAYER UNIFORMITY IMPROVEMENT OF DEPOSITION-INHIBITION-DEPOSITION PROCESSES

(71) Applicant: Lam Research Corporation, Fremont, CA (US)

(72) Inventors: Krishna BIRRU, Fremont, CA (US); Leonard KHO, San Francisco, CA (US); Jasmine Yuen-Sen LIN, San Jose, CA (US); Raul VYAS, Fremont, CA (US); Anand CHANDRASHEKAR, Fremont, CA (US); Jeff CLEVENGER, Morgan Hill, CA (US)

(73) Assignee: Lam Research Corporation, Fremont, CA (US)

(21) Appl. No.: 18/832,042

(22) PCT Filed: Feb. 28, 2023
(86) PCT No.: PCT/US2023/014094

§ 371 Date: Jul. 22, 2024

Related U.S. Application Data
(60) Provisional application No. 63/268,771, filed on Mar. 2, 2022.

(51) Int. Cl. C23C 16/458; C23C 16/455; C23C 16/52

(52) U.S. Cl. CPC C23C 16/4583; C23C 16/45565; C23C 16/52

(57) ABSTRACT

Disclosed herein is a process tool, comprising a wafer chuck and a showerhead. In at least one implementation, wafer chuck is coupled to a motor that is operable to vertically displace wafer chuck relative to showerhead. In at least one implementation, a carrier ring is between wafer chuck and showerhead. In at least one implementation, carrier ring comprises an overhang extending over an edge of a wafer on the wafer chuck. In at least one implementation, carrier ring is mechanically coupled to a spindle operable to vertically displace carrier ring relative to wafer chuck.

### CLAIM OF PRIORITY

This application claims priority of U.S. Provisional Application 63/268,771, filed Mar. 2, 2022, titled “LAYER UNIFORMITY IMPROVEMENT OF DEPOSITION-INHIBITION-DEPOSITION PROCESS,” which is incorporated in its entirety.

### BACKGROUND

Processing tools are used to perform treatments such as deposition and etching of film on substrates like semiconductor wafers. For example, deposition may be performed to deposit a conductive film, a dielectric film, or other types of film using chemical vapor deposition (CVD), plasma enhanced CVD (PECVD), atomic layer deposition (ALD), plasma enhanced ALD (PEALD), and/or other deposition processes. Deposition may be performed in a wafer processing chamber such as a PECVD chamber comprising multiple stations for processing more than one wafer at a time.

Multi-station semiconductor process tools may employ carrier rings to transfer wafer substrates between stations. Carrier ring may remain with wafer until process is finished, then carry the wafer to the next station or to a transfer paddle that takes the wafer to a loading dock for removal. In some CVD and PECVD tools, a carrier ring may be employed to help prevent deposition of layers on the edge or backside of the wafer, where it is not desired. Some carrier ring may have a diameter slightly larger than a wafer to shield the periphery and backside from deposition vapors. Without such shielding of the periphery, nucleation of deposition materials may be encouraged on both the periphery and backside of the wafer, where layer growth may be faster than growth within the interior regions of the wafer substrate. Layer thickness uniformity on the front side of the wafer may suffer, where deposited layers may be thicker near the edges of the substrate than in the center. Other processes may include an inhibitor step to discourage formation of voids caused by rapid growth of material at the top of high aspect ratio trenches or holes. By use of the same ring to shield the periphery, inhibitors of layer growth may not reach peripheral regions of the wafer substrate, causing voids at the periphery of the layer. As a result, layer non-uniformity may increase. One solution is to have the ability to replace one ring or use well-tuned ring dimensions at each process station to accommodate different processes. This solution is mostly impractical because multiple rings having unique designs would be required for performing many different processes performed in the same process tool.

### BRIEF DESCRIPTION OF THE DRAWINGS

Material described herein is illustrated by way of example and not by way of limitation in accompanying figures. For simplicity and clarity of illustration, elements illustrated in figures are not necessarily drawn to scale. For example, dimensions of some elements may be exaggerated relative to other elements for clarity. Also, various physical features may be represented in their simplified “ideal” forms and geometries for clarity of discussion, but it is nevertheless to be understood that practical implementations may only approximate illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among figures to indicate corresponding or analogous elements.

FIG. 1 illustrates a cross-sectional view of a process chamber, in accordance with at least one implementation.

FIG. 2 illustrates a plan view of a showerhead comprising a square aperture pattern and for a single process gas, in accordance with at least one implementation.

FIG. 3 illustrates a plan view of a showerhead comprising a dual interpenetrating aperture pattern for distribution of two process gases, in accordance with at least one implementation.

FIG. 4A illustrates a plan view of an internal portion of a dual-plenum showerhead, in accordance with at least one implementation.

FIG. 4B illustrates a cross-sectional view of internal portion of dual-plenum showerhead shown in FIG. 4A, in accordance with at least one implementation.

FIG. 5 illustrates a cross sectional view of a semiconductor process tool comprising process chamber of FIG. 1, in accordance with at least one implementation.

FIG. 6 illustrates a plan view of a semiconductor process tool comprising multiple process stations, in accordance with at least one implementation.

FIGS. 7A-7D illustrate cross-sectional views of a process chamber comprising a movable wafer chuck and carrier ring at different positions during a process, in accordance with at least one implementation.

FIG. 8 illustrates an exemplary process flow chart for a multi-station process tool performing parallel processes, in accordance with at least one implementation.

FIG. 9 illustrates an exemplary process flow chart for a method of operating a process chamber, in accordance with at least one implementation.

### DETAILED DESCRIPTION

Here, numerous specific details are set forth, such as structural schemes, to provide a thorough understanding of at least one implementation. It will be apparent to one skilled in art that at least one implementation may be practiced without these specific details. In other instances, well-known features, such as gas line tubing fittings, heating elements and snap switches, are described in lesser detail to not unnecessarily obscure at least one implementation. Furthermore, it is to be understood that at least one implementation shown in figures are illustrative representations and are not necessarily drawn to scale.

In some instances, well-known methods and devices are shown in block diagram form, rather than in detail, to avoid obscuring at least one implementation. Reference throughout this specification to “an implementation” or “one implementation” “at least one implementation” or “some implementations” means that a particular feature, structure, function, or characteristic described in connection with an implementation is included in at least one implementation. Thus, appearances of phrase “in an implementation” or “at least one implementation” or “in one implementation” or “some implementations” in various places throughout this specification are not necessarily referring to a same implementation. Furthermore, particular features, structures, functions, or characteristics may be combined in any suitable manner in one or more implementations. For example, a first implementation may be combined with a second implementation anywhere particular features, structures, functions, or characteristics associated with first and second implementations are not mutually exclusive.

To address limitations described above, methods and apparatuses are disclosed for adjusting a distance between a wafer and a carrier ring (wafer-ring gap, WRG, also may be termed pedestal-to ring gap, PRG). Here, methods and apparatus also include adjustment of gap between a wafer and a showerhead (wafer-showerhead gap, WSG), in accordance with at least one implementation. According to at least one implementation, a carrier ring may be raised or lowered to desired z-heights over wafer by a spindle to which carrier ring is coupled. In at least one implementation, spindle may be commanded to establish a first gap, defined as a specific distance (e.g., a gap) between wafer and carrier ring (hereinafter referred to as “wafer-ring gap” or “WRG”).

In at least one implementation, a WRG may be adjusted by commanding spindle to move vertically to a specified z-height relative to a reference position of spindle. In at least one implementation, commands may be encoded in software that is executable by a processor (e.g., a microprocessor). In at least one implementation, software may comprise commands as binary instructions for spindle that are callable by process recipe subroutines stored in a memory coupled to a processor. In at least one implementation, processor may be integral in a control module (e.g., a human-machine interface, HMI) as part of a process tool control module. In at least one implementation, the carrier ring may be lifted and lowered accordingly. In at least one implementation, by optimization of WRG (WRG may also be referred to as pedestal-ring gap, PRG), uniformity of a deposition layer resulting from CVD and PECVD processes may be improved. In at least one implementation, increasing WRG during introduction of a film growth inhibition gas may enable flow of inhibition gas to periphery of a wafer. In at least one implementation, an inhibition gas can inhibit growth of a deposited layer at and near edges of a wafer. As a result, in at least one implementation, material deposition at wafer edge and backside is inhibited. In at least one implementation, by following this or a similar procedure, uniformity of layer thickness may be improved by as much as 60%.

In at least one implementation, adjustment of WRG affords employment of a single carrier ring design for a number of different processes (e.g., identical carrier rings deployed at each station in a multi-station process tool). In at least one implementation, where attainment of wafer periphery by process gases may be undesirable in certain processes, it may be desirable in other processes.

In at least one implementation, carrier ring is an annular ring positioned above wafer. In at least one implementation, a carrier ring may be substantially concentric with wafer chuck. In at least one implementation, carrier ring may further comprise fingers on its lower side that engage wafer to lift it off a wafer chuck. In at least one implementation, carrier ring has an inner lip (at an inner diameter) that overhangs an edge of a wafer. In at least one implementation, an amount of overhang may be optimized. In at least one implementation, overhang of inner lip with outer edge of wafer may shield edge of wafer from exposure to process gases. In at least one implementation, to effectuate such shielding, carrier ring may lay directly on wafer or be raised a small distance over wafer.

In at least one implementation, during a CVD deposition, wafer may use a suitable photomask or shadow mask to prevent deposition of material on edge and backside of wafer. In at least one implementation, such edge growth may be faster than interior growth, causing non-uniformity in a final layer. In at least one case, undesirable layer formation on wafer backside may also occur. In at least one implementation, providing a carrier ring having a suitable overhang of wafer periphery and adjustable WRG may obviate use of a mask layer for wafer to avoid non-uniformities and backside deposition, saving time and extra cost. In at least one implementation, WRG may be decreased to a specified distance to reduce flow of CVD process gases to edge of wafer.

In at least one implementation, it may be desired to flow of one or more process gases to an edge of a wafer, where process gases may chemically inhibit nucleation of precursors. In at least one implementation, incipient crystal formation from deposited film precursors may provide nucleation sites for layer growth. In at least one implementation, precursor vapors impinging on surface encounter incipient nanocrystals and further react and crystallize on nanocrystals themselves, causing nanocrystals to grow into larger crystals that merge to form a compact or porous layer.

In at least one implementation, nucleation may also occur within material layers previously deposited. In at least one implementation, a previously deposited layer may be etched to produce trenches that are to be filled by a different material. In at least one implementation, undesirable nucleation of second material may occur at upper reaches of trench sidewalls, for example, where further deposition of second material may close top of trench rather than fill trench, creating voids in layer. In at least one implementation, nucleation inhibitors may be included in gaseous form as one of process gases to prevent such occurrences.

Trench sidewalls may then be exposed to a nucleation inhibitor gas in a subsequent step to prevent growth only at top of trenches during second deposition, causing formation of voids. In at least one implementation, to encourage flow of inhibitor to periphery of wafer, WRG may be increased by raising of carrier ring by software or HMI commands sent to spindle to raise its z-height by a specified amount relative to its reference position.

In at least one implementation, stations within a multi-station process tool may include a showerhead, directly over each chuck. In at least one implementation, process gases issue from multiple apertures in faceplate of a showerhead, so named due to resemblance to a household showerhead. In at least one implementation, apertures may be organized in any suitable manner such as columns and rows. In at least one implementation, apertures may be arranged in a square array geometry. In at least one implementation, other suitable array geometries may be used, such as a hexagonal array geometry. In at least one implementation, showerheads employed in process tools are cylindrical, having a round cross section. In at least one implementation, showerheads may have square or other non-circular geometries. In at least one implementation, a showerhead may be positioned over a wafer chuck and may be concentric therewith. In at least one implementation, in multi-station process tools, a showerhead may be present. In at least one implementation, showerheads may be positioned over their respective pedestals.

In at least one implementation, a wafer chuck may comprise a platen upon which a wafer is placed and clamped. In at least one implementation, clamping of wafer to chuck may be accomplished by electrostatic clamping (ESC) or vacuum clamping (lower pressure on backside of wafer compared to front side of wafer). Here “column” may generally refer to an elongated tubular housing for routing of cables, wires as well as vacuum and gas delivery tubing. A chuck may be attached to a column. In at least one implementation, a pedestal comprises combination of chuck and column. In at least one implementation, cables and wires vacuum lines and gas tubing housed within column may bring electrical signals to electrodes within chuck. In at least one implementation, electrodes may be ESC electrodes or plasma electrodes. In at least one implementation, gas tubing may carry a purge gas to chuck, for example, which may be especially useful for purging any undesirable processes gases that may flow within WRG. In at least one implementation, purge gases may dilute process gases carrying deposition precursor vapors, and generally preventing them from forming layers on edge and backside of wafer.

In at least one implementation, a second gap is defined as a distance between wafer and showerhead. In at least one implementation, a wafer-showerhead gap (WSG) may be an additional adjustable parameter in a process. In at least one implementation, a WSG may also be adjusted on command to refine a process beyond what is obtainable by adjustment of WRG alone. In at least one implementation, in multi-station process tools, carrier rings having substantially identical dimensions may be deployed at all stations in a multi-station process tool. In at least one implementation, carrier ring may be utilized at one station to shield edge of a wafer. In at least one implementation, wafers at other stations in a multi-station process tool may be exposed to overflow gases from an active station. In at least one implementation, shielding of other wafers may be afforded by reducing WSG between wafer and showerhead.

In at least one implementation, WSG may be reduced by lifting a wafer toward showerhead that is above it. In at least one implementation, adjustment of WSG may be included in a process recipe to regulate layer growth at a station where a deposition is occurring. In at least one implementation, flow intensity may be regulated to fine tune a deposition process by adjustment of a WSG. In at least one implementation, WSG at a process station may be tuned to regulate flow intensity of process gases over a wafer. In at least one implementation, flow intensity may be defined as a gas flux per unit area, for example, a flow rate per square centimeter. In at least one implementation, tuning of WRG and WSG at a process station may obviate need to install multiple carrier rings for each process when a change of process is foreseen.

In at least one implementation, a third parameter, in combination with WRG and WSG tuning, is showerhead aperture size and pattern. In at least one implementation, aperture size and pattern of a showerhead may be optimized to reduce nonuniformity of deposited layers in DID processes and in other CVD processes where inhibition step is omitted. In at least one implementation, a showerhead aperture pattern may be optimized as a square array for a particular process or group of processes. In at least one implementation, a showerhead aperture pattern may be optimized as a hexagonal pattern for a particular process or group of processes. In at least one implementation, a showerhead aperture pattern may be optimized as a radial pattern for a particular process, whereby apertures maybe be substantially equidistant along radii of a faceplate.

In at least one implementation, in multi-station deposition chambers, transfer of wafers from station to station may be performed by a single transfer ring. In at least one implementation, ring edge may overhang wafer edge by a distance that may be optimized for a specific process carried out at a particular station. In at least one implementation, overhang may be optimized at a station where a deposition inhibition step is carried out.

In at least one implementation, same carrier ring may be moved to other process stations within process tool where it may be employed as an edge deposition shield. In at least one implementation, as an edge deposition shield, carrier ring can prevent layers from growing on edge and backside of a wafer. In at least one implementation, nucleation or bulk deposition steps may be carried out at one or more process stations. Having a single carrier ring available, performance of those processes carried out at other stations may be adversely affected by narrow optimization of overhang.

In at least one implementation, this problem may be solved by adjusting gap between wafer and carrier ring (WRG) and gap between wafer and showerhead (WSG). In at least one implementation, one or more of process stations may host a number of multistep processes. In at least one implementation, processes may employ shielding of wafer edge and backside of a wafer to adequately prevent unwanted layer deposition. In at least one implementation, shielding of wafer edge and backside may be effectuated by providing a tuned carrier ring overhang.

Generally, an optimized WRG or PRG may be fixed for a particular process to prevent such unwanted deposition. To host a number of different processes at one station or share processes between two or more stations, in at least one implementation, process recipes may contain software-encoded process recipe steps as commands to adjust WRG and/or WSG uniquely for each process for which recipes may be stored in a process library. In at least one implementation, as such, a single carrier ring may be employed for different processes at a single station or at different stations, where different processes each have an optimal WRG and/or WSG. In at least one implementation, process recipes may be copied as software into a command module of process tool to adjust WRG or WSG accordingly.

Here “coupled” and “connected,” along with their derivatives, may be used herein to describe functional or structural relationships between components. These terms are not intended as synonyms for each other. Rather, in particular implementations, “connected” may be used to indicate that two or more elements are in direct physical, optical, or electrical contact with each other. Here, “Coupled” may be used to indicated that two or more elements are in either direct or indirect (with other intervening elements between them) physical, electrical or in magnetic contact with each other, and/or that two or more elements co-operate or interact with each other (e.g., as in a cause an effect relationship).

Here “over,” “under,” “between,” and “on” as used herein refer to a relative position of one component or material with respect to other components or materials where such physical relationships are noteworthy. Unless these terms are modified with “direct” or “directly,” one or more intervening components or materials may be present. Similar distinctions are to be made in context of component assemblies. As used throughout this description, and in claims, a list of items joined by “at least one of” or “one or more of” can mean any combination of listed terms.

Here, “adjacent” here generally refers to a position of a thing being next to (e.g., immediately next to or close to with one or more things between them) or adjoining another thing (e.g., abutting it).

Unless otherwise specified in explicit context of their use, terms “substantially equal,” “about equal” and “approximately equal” mean that there is no more than incidental variation between two things so described. Such variation is typically no more than +/−10% of referred value.

Here, “WRG” generally refers to a small distance between a wafer surface and a surface of carrier ring that contacts wafer.

Here, “wafer” may generally refer to a semiconductor substrate shaped as a disc having a diameter. In at least one implementation, diameter depends on various technologies of wafer. In at least one implementation, diameter ranges generally between 3 cm and 30 cm. In at least one implementation, other sizes may be used.

Here, “carrier ring” may generally refer to an annular structure that physically lifts, carries, and places wafer on a wafer chuck or pedestal (defined below).

Here, “software-encoded process step” may generally refer to process recipes that may contain software-encoded process recipe steps as commands to adjust WRG and/or WSG uniquely for each process for which recipes may be stored in a process library.

Here “process gas” generally refer to a combination of gases and vapors, inert and reactive, employed for plasma formation, as well as deposition precursor vapors.

Here, “gap” may generally refer to a spacing or distance between two adjacent surfaces or objects.

Here “process tool” may generally refer to a fabrication tool comprising a vacuum chamber in which semiconductor fabrication processes may be performed. In at least one implementation, a process tool can have many other components such as chuck, showerhead, carrier ring, etc.

Here “vacuum chamber” may generally refer to an evacuated enclosure for processing purposes such as deposition, etching, etc.

Here, “multi-station process tool” may generally refer to a semiconductor process tool comprising one or more process stations within vacuum chamber.

Here, “process station” may generally refer to a combination of a wafer chuck and a process gas distribution showerhead. In at least one implementation, in a multi-station process tool, two or more process stations may be arranged within vacuum chamber. In at least one implementation, an individual process station within a multi-station process tool may be dedicated to a particular process.

Here, “rotary indexer” may generally refer to a mechanism designed to transfer wafers between process stations within a multi-station process tool.

Here, “showerhead” may generally refer to a two-dimensional or a three-dimensional gas manifold. In at least one implementation, output of manifold may be a controlled distribution of a fluid such as gas, liquid, vapor, etc.

Here, “motor” may generally refer to an electric motor, such as an alternating current (ac) motor, a universal motor or a DC motor such as a servomotor or a stepper motor. In at least one implementation, servomotors and stepper motors may be precision controlled.

Here “idle position” may generally refer to a configuration of a device when it is not being actively used. In at least one implementation, a z-height of a carrier ring or a pedestal is in an idle position when not currently engaged in a process.

Here, “initial position” may generally refer to an initial z-height position of a carrier ring or pedestal at start of a process, for example.

Here, “operational position” may generally refer to a z-height position of a carrier ring or pedestal when engaged in a process. In at least one implementation, an initial position is an example of an operational position.

Here, “z-height” may generally refer to a vertical distance or height above some reference level.

Here, “reference position” may generally refer to a reference datum within a piece of equipment, such as a vacuum chamber of a process tool. In at least one implementation, reference position is zero level to which z-heights may be referenced.

Here, “process gas” may generally refer to an inert or reactive gases such as argon, nitrogen, oxygen, hydrogen, hydrazine, etc., and may also include precursor vapors that are generated as sublimation products or as gases at room temperature.

Here, “process gas source” may generally refer to a pressurized container or tank that contains a process gas (e.g., Argon, Nitrogen, precursor, etc.).

Here, “nucleation layer” may generally refer to a pre-deposition layer that is deposited to sub-micron thicknesses. In at least one implementation, nucleation layer may comprise nanocrystals on which condensing deposition precursor vapors may crystallize and grow. In at least one implementation, same process gases may crystalize on second wafer if it is exposed.

Here, “processor” may generally refer to a semiconductor computing device, commonly in a monolithic microchip package. In at least one implementation, processor may be a microcontroller coupled to a memory and/or other components. In at least one implementation, processor may have single or multiple processor cores.

Here, “memory” may generally refer to a semiconductor device capable of storing computer code and data. In at least one implementation, computer code may be in a binary format. In at least one implementation, memory can be volatile or non-volatile in nature. In at least one implementation, memory can be embedded in processor or externally coupled to it.

Here, “software” or “firmware” may generally refer to machine-readable or machine-executable binary code comprising instructions for controlling actuating devices coupled to movable components within vacuum chamber of a process tool.

Here “motion-control subroutines” may generally refer to a computer executable set of instructions that contain motor commands. In at least one implementation, motion-control subroutines may be callable by one or more machine process recipe steps that are encoded in multiple software instructions and stored in memory.

Here, “human-machine interface” may generally refer to circuitry coupled to an interface, such as a control panel having buttons, switches, etc., and may include a touch screen.

Here, “nucleation” generally refers to an incipient crystallization of precursor vapors deposited and undergoing chemical reaction on a surface, forming a nucleation layer.

Here, “nucleation layer” generally refers to a layer comprising surface-bound molecules or incipient nano-scale crystals grown by reaction of surface-bound molecules with impinging gas-phase molecules during a material deposition process such as CVD.

Here, “inhibitor” or “nucleation inhibitor” generally refers to a material that prevents nucleation or deposition of another material on a surface. In at least one implementation, processes that include inhibitor gases or vapors may include a sequence of deposition-inhibition-deposition (DID), for example.

Here, “showerhead” refers generally to a gas distribution manifold employed in deposition and etch chambers in semiconductor process tools, a showerhead may have a two-dimensional array of apertures fluidically coupled to one or two plenums from which process gases issue. In at least one implementation, apertures may extend through a faceplate at lower surface of a showerhead, where faceplate faces a wafer substrate below.

Here, “faceplate” generally refers to lower surface of a showerhead through which apertures extend.

Here, “plenum” generally refers to a main channel or chamber coupled to multiple openings (e.g., apertures) or channels arranged in a pattern through which a fluid issue.

Here “aperture” generally refers to an opening or void in a material such as a showerhead faceplate. In at least one implementation, opening may be of any suitable shape and size. A collection of such openings is referred to as an array of apertures.

Here, “wafer chuck” may generally refer to a device for placing and holding a wafer for processing. In at least one implementation, wafer chuck may include a clamping mechanism for securing a wafer to wafer chuck, such as an electrostatic clamping (ESC) mechanism or vacuum clamping (differential pressure between front and back of wafer).

Here, “pedestal” may generally refer to a column supporting a wafer chuck.

Here, “vacuum chamber” may generally refer to an enclosure evacuated to a high vacuum. In at least one implementation, vacuum chamber may be employed for carrying out semiconductor fabrication processes, such as CVD and etching processes.

Here, “spindle” generally refers to a mechanism comprising a rod or axle that is actuated to rotate and/or translate along its axis. In at least one implementation, a spindle may displace and rotate a carrier ring.

Here “overhang” generally refers to a distance inner lip of carrier ring extends over wafer from edge of wafer.

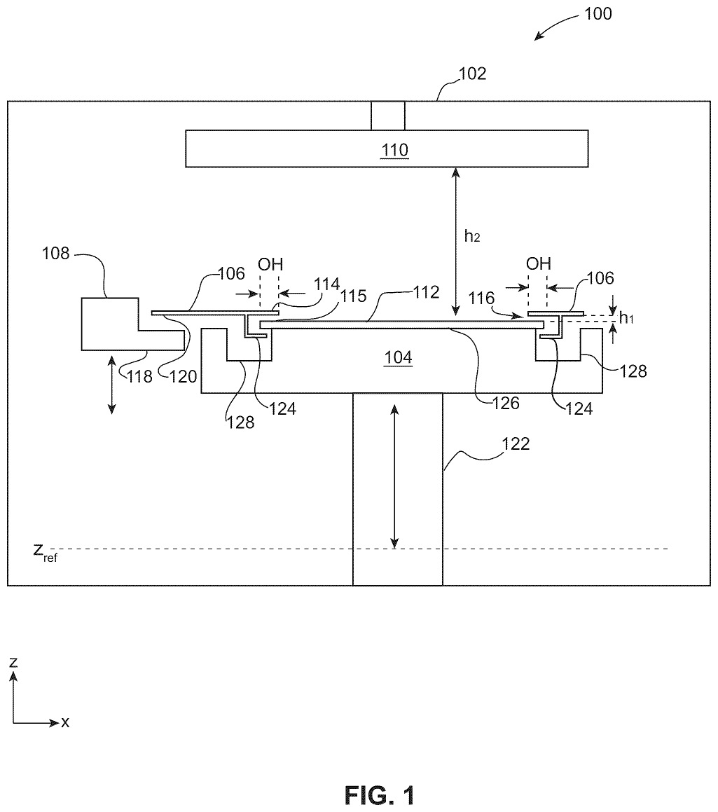

FIG. 1 illustrates a cross-sectional view of process tool 100, in accordance with at least one implementation. In at least one implementation, process tool 100 comprises vacuum chamber 102, wafer chuck 104, carrier ring 106, spindle 108, and process gas distribution showerhead 110 (henceforth, showerhead 110). In at least one implementation, vacuum chamber 102 may comprise multiple process stations (one is shown), each station comprising a wafer chuck such as wafer chuck 104 and showerhead such as showerhead 110. In at least one implementation, spindle 108 may be an end-effector (e.g., hand, transfer paddle) of a robot arm within vacuum chamber 102.

In at least one implementation, showerhead 110 may be located directly over wafer chuck 104. For example, showerhead 110 may be concentric with wafer chuck 104. In at least one implementation, carrier ring 106 is concentric with wafer chuck 104. In at least one implementation, carrier ring 106 may be mechanically coupled to spindle 108. In at least one implementation, wafer 112 is shown to be seated on wafer chuck 104. In at least one implementation, carrier ring 106 comprises an overhang 114 that extends a distance OH over periphery of wafer 112. In at least one implementation, overhang 114 can protect edge (115) and backside (126) of wafer 112 from material deposition. In at least one implementation, distance OH of overhang 114 may be optimized to limit mass flow of process gases to edge and backside regions of wafer 112.

In at least one implementation, carrier ring 106 is vertically displaced from wafer 112 by a vertical displacement (e.g., a change of z-height) of spindle 108. In at least one implementation, spindle 108 may lift carrier ring 106 a height h₁ over wafer 112, forming a wafer-to-ring gap (WRG) 116. In at least one implementation, WRG 116 may be adjustable within a range of vertical heights relative to wafer 112 by vertical displacement of spindle 108. In at least one implementation, upward movement of spindle 108 may engage shelf 118 with edge 120 of carrier ring 106, lifting carrier ring 106 to increase gap spacing h₁ of WRG 116. In at least one implementation, downward movement of spindle 108 may lower carrier ring 106, decreasing gap spacing h₁ of WRG 116. In at least one implementation, spindle 108 may be disengaged from carrier ring 106, permitting carrier ring 106 to rest on wafer chuck 104, whereby wafer-to-ring gap (WRG) may be zero.

In at least one implementation, wafer chuck 104 may be vertically displaced with respect to showerhead 110 (or to a reference position within vacuum chamber 102, for example, z_{ref},) by vertical motion of pedestal 122. In at least one implementation, pedestal 122 may be actuated by a motor (not shown). In at least one implementation, position of showerhead 110 is fixed. In at least one implementation, showerhead 110 may be vertically displaced by motor actuation. In at least one implementation, vertical displacement of wafer chuck 104 relative to showerhead 110 may enable adjustment of wafer-to-showerhead gap (WSG) distance h₂.

In at least one implementation, carrier ring 106 comprises fingers 124, enabling engagement of carrier ring with wafer 112 to suspend and carry it between process stations. In at least one implementation, carrier ring 106 may be engaged by spindle 108. In at least one implementation, spindle 108 is a robot arm or an end-effector attached to a robot arm. In at least one implementation, wafer 112 may be raised above wafer chuck 104 by engagement of fingers 124 with backside 126 of wafer 112 a carrier ring 106 is lifted. In at least one implementation, carrier ring 106 may carry wafer 112 to a succeeding process station. In at least one implementation, after transfer of wafer 112, fingers 124 may be stowed inside of pockets 128.

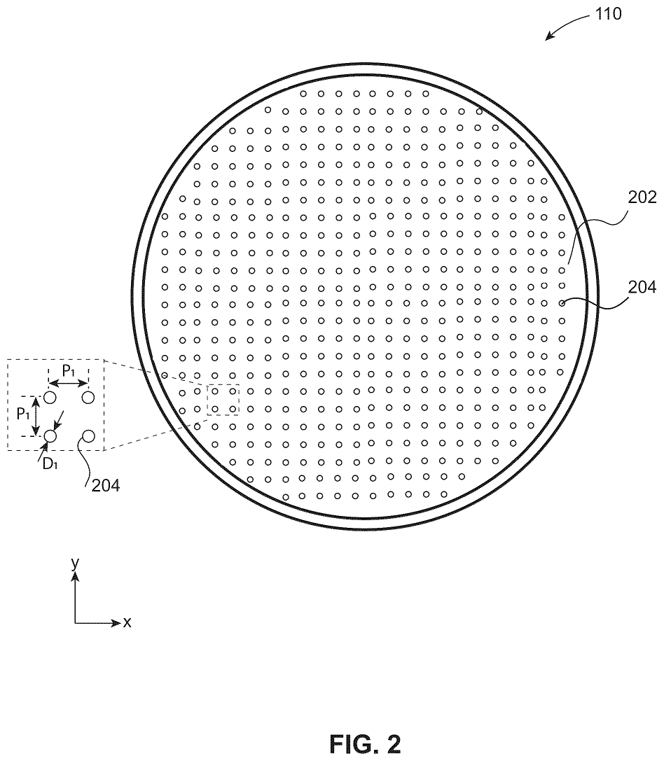

FIG. 2 illustrates a plan view of showerhead 110, in accordance with at least one implementation. In at least one implementation, showerhead 110 comprises faceplate 202. In at least one implementation, faceplate 202 is positioned within lower portion of showerhead 110. In at least one implementation, faceplate 202 may be positioned directly overhead of a wafer chuck at a process station (e.g., wafer chuck 104 in FIG. 1). In at least one implementation, faceplate 202 comprises a plurality of apertures 204. In at least one implementation, apertures 204 may be uniformly distributed over faceplate 202. In at least one implementation, apertures 204 may be arranged in a square array, as shown. In at least one implementation, while apertures 204 have a uniform center-to-center pitch P₁ in both x and y directions, as shown in inset, other types of distributions of apertures 204 may be employed. In at least one implementation, apertures 204 can be distributed in a hexagonal array pattern. In at least one implementation, apertures 204 may have a uniform diameter D₁ that ranges between 1 mm and 5 mm.

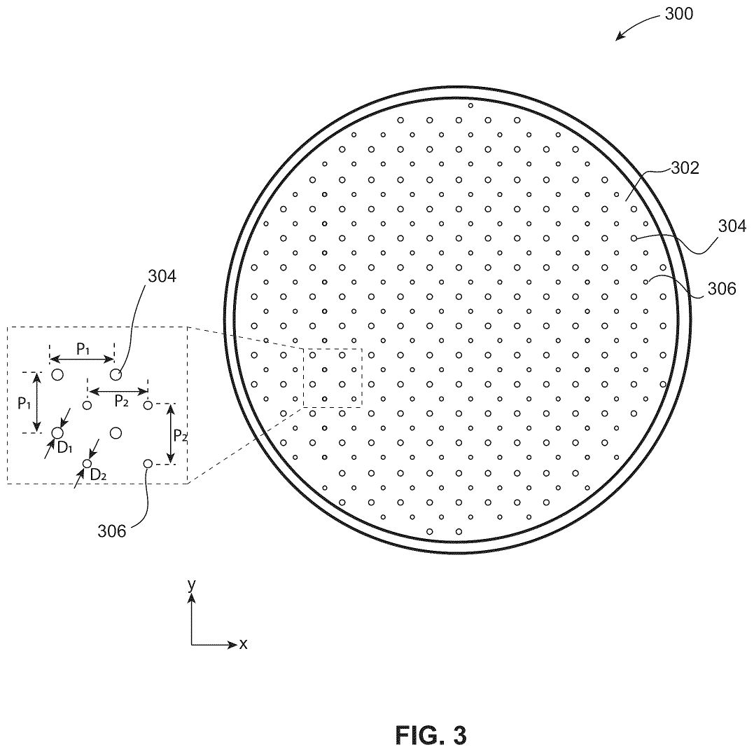

FIG. 3 illustrates a plan view of showerhead 300, comprising faceplate 302. IN at least one implementation, showerhead 300 is substantially like showerhead 110 in overall dimensions, but differ in internal construction, as described below. In at least one implementation, faceplate 302 comprises two sets of apertures 304 and 306, arranged in two interpenetrating arrays. In at least one implementation, two arrays are square arrays. In at least one implementation, while a square array pattern is shown, apertures 304 and 306 may be arranged in any suitable pattern. In at least one implementation, for example, apertures 304 and 306 may be arranged in a radial pattern, whereby inter-aperture spacing may be substantially uniform along radii of faceplate 302. In at least one implementation, apertures 304 have a diameter D₁ and center-to-center pitch P₁. In at least one implementation, apertures 306 have a diameter D₂ and center-to-center pitch P₂ (e.g., as shown in inset). In at least one implementation, pitch P₂ is substantially equal to pitch P₁. In at least one implementation, diameters D₁ and D₂ range between 0.5 mm and 2 mm. In at least one implementation, D₂ is less than D₁.

In at least one implementation, apertures 304 and 306 are coupled to separate plenums within showerhead 110, as will be described below. In at least one implementation, apertures 304 and 306 may distribute a first process gas and a second process gas, respectively, over a wafer (e.g., wafer 112) during a deposition process, for example. In at least one implementation, wafer may be positioned on a pedestal (e.g., chuck 104) below showerhead 110.

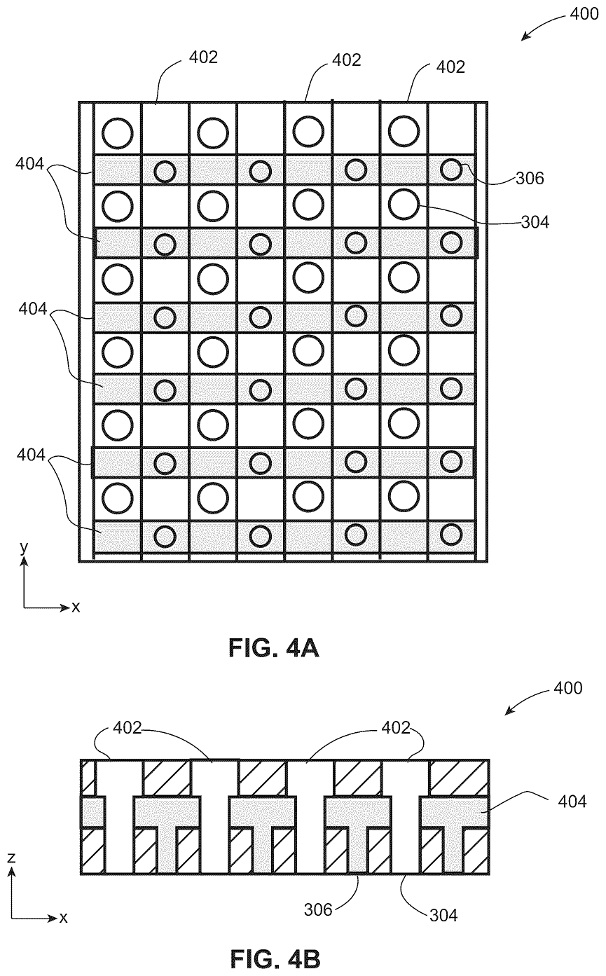

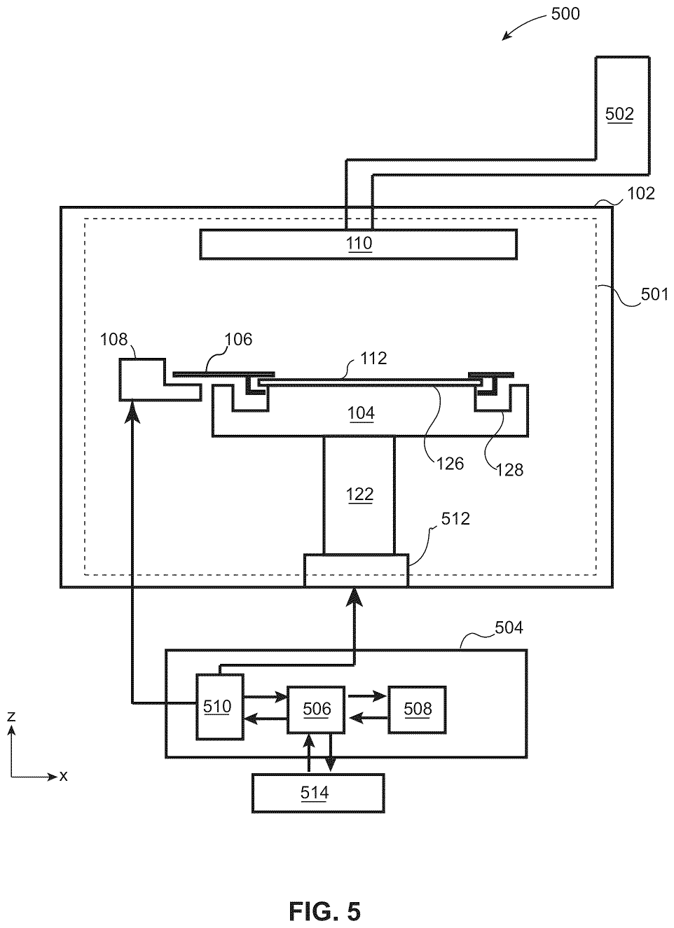

FIG. 4A illustrates a plan view of internal region 400 of showerhead 300, in accordance with at least one implementation. In at least one implementation, a first plurality of plenums 402 extend in y-direction of figure. In at least one implementation, plenums 402 are in coupled to apertures 304. In at least one implementation, plenums 402 may be coupled to a first process gas.

In at least one implementation, a plurality of plenums 404 (shaded in grey) extend in x-direction of figure, orthogonally to plenums 402. In at least one implementation, plenums 404 are coupled to apertures 306. In at least one implementation, plenums 404 may be coupled to a second process gas.

In at least one implementation, each of apertures 306 are offset from adjacent apertures 304 both in x- and y-directions. In at least one implementation, apertures 306 are offset from apertures 304 by a distance approximately equivalent to P₁/2 and/or P₂/2. In at least one implementation, other suitable geometries may be considered. In at least one implementation, plenums 402 and 404 are at different vertical levels (e.g., z-heights) in showerhead 300, as described below.

FIG. 4B illustrates a cross-sectional view in x-z plane of internal region 400 of showerhead 300, in accordance with at least one implementation. In at least one implementation, plenums 402 extend orthogonally to plenums 404 (e.g., in y-direction, or above and below plane of figure). In at least one implementation, plenums 404 extend along x-direction of figure. In at least one implementation, plenums 402 and 404 are collocated at different z-heights within showerhead 300. In at least one implementation, vertical displacement of plenums 402 and 404 enable crisscrossing of plenums 402 and 404 without intersection.

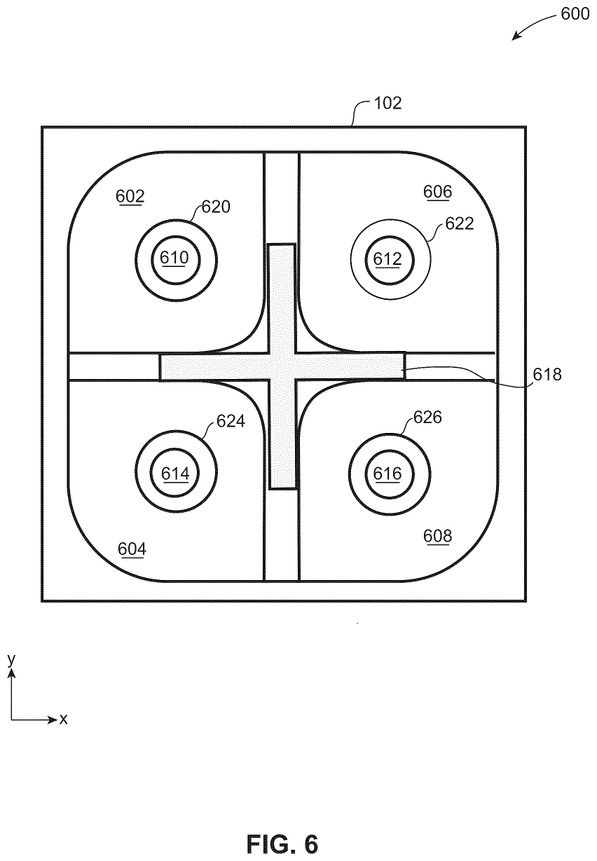

FIG. 5 illustrates a cross-sectional view of a process tool 500 comprising a single process station 501, in accordance with at least one implementation. In at least one implementation, process station is delineated by dashed enclosure. In at least one implementation, process station 501 comprises showerhead 110 and chuck 104. In at least one implementation, chuck 104 is supported by pedestal 122. In at least one implementation, showerhead 110 is coupled to process gas source 502.

In at least one implementation, process tool 500 may be a semiconductor fabrication tool comprising vacuum chamber 102. In at least one implementation, vacuum chamber 102 may be configured as an etch and/or deposition chamber, such as a vacuum chamber employed in plasma etching or chemical vapor deposition (CVD) processes. In at least one implementation, controller 504 may be electrically coupled to spindle 108 (or a robot arm, a rotary indexer, not shown) and motor 512 to move pedestal 122.

In at least one implementation, controller 504 comprises processor 506 and memory 508. Memory 508 is electrically coupled to processor 506. In at least one implementation, memory 508 comprises storage for binary code software or firmware that is executable by processor 506. In at least one implementation, binary code may comprise encoded software instructions to adjust WRG (e.g., vertical height of carrier ring 106 with respect to wafer 112). In at least one implementation, binary code may include multiple software instructions to adjust WSG (e.g., vertical height of wafer chuck relative to showerhead 110). In at least one implementation, processor 506 is electrically coupled to output circuit 510. In at least one implementation, pedestal 122 may be actuated by motor 512, which can be driven by motor actuation circuitry contained within output circuit 510.

In at least one implementation, multiple software instructions may include motion control subroutines for synchronous or non-synchronous motion control of spindle 108 and motor 512. In at least one implementation, motion-control subroutines may be callable by one or more machine process recipe steps that are encoded in multiple software instructions and stored in memory 508. In at least one implementation, machine process recipe steps may be called by a human-machine interface (HMI) 514. In at least one implementation, process recipe may be selected by a human operator who may call one or more motion-control subroutines by pressing buttons or a touch screen on a panel of HMI 514. In at least one implementation, once chosen, process recipe instructions may operate process tool automatically. In at least one implementation, controller 504 may also be operable to be commanded directly by HMI 514, whereby a human operator manually operates process tool 500. In at least one implementation, human operator may directly raise and lower carrier ring 106 and wafer chuck 104 by pressing buttons or selecting options on a touch screen, for example.

In at least one implementation, binary code may include software instructions for controlling flow rate of process gases entering showerhead 110. In at least one implementation, software instructions may also direct control of flow rates of inert gases introduced through chuck 104, below wafer 112. In at least one implementation, inert gases introduced through chuck 104 may help to control flow of process gases over edge of wafer 112, preventing deposition on backside 126 of wafer 112.

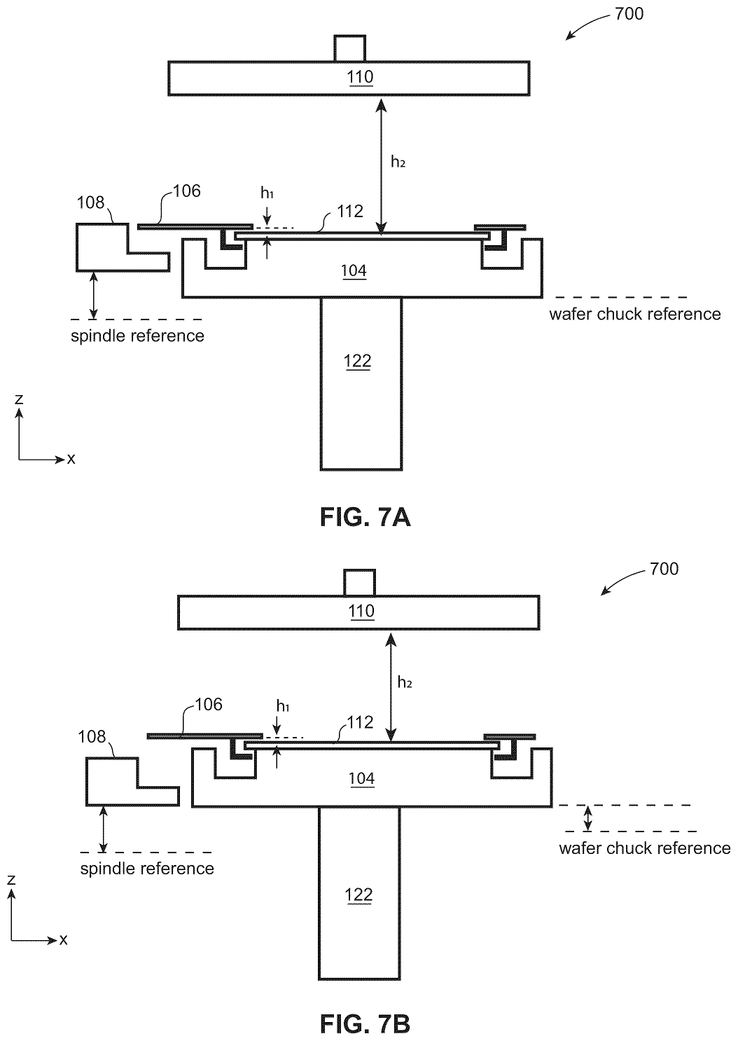

FIG. 6 illustrates a plan view of multi-station process tool 600, in accordance with at least one implementation. In at least one implementation, multi-station process tool 600 comprises process stations 602, 604, 606, and 608. In at least one implementation, any of process stations 602, 604, 606, and 608 may be substantially identical to process station 501 shown in FIGS. 1 and 5. In at least one implementation, process stations 602, 604, 606, and 608 comprise wafer chucks 610, 612, 614, and 616, respectively. In at least one implementation, process tool 600 comprises rotary indexer 618 to transfer a wafer (e.g., wafer 112) between wafer chucks 610-616. In at least one embodiment, process tool 600 comprises carrier rings 620, 622, 624, and 626 deployed at process stations 602, 604, 606, 608, respectively.

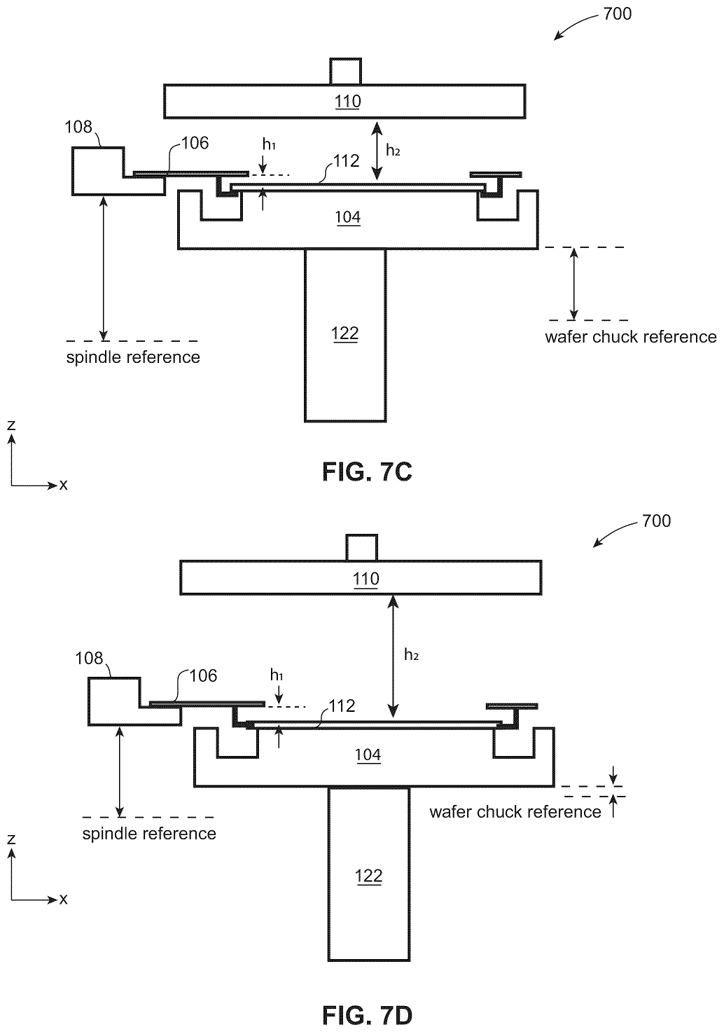

FIGS. 7A-7D illustrate a series of cross-sectional views of process tool 700, in accordance with at least one implementation. In at least one implementation, process tool 700 may be substantially same as process tool 100. In at least one implementation, referring to FIG. 7A, process tool 700 is in a state prior to start of a process. Reference positions are shown for spindle 108 and for wafer chuck 104, respectively. In at least one implementation, initial wafer-carrier ring gap WRG gap h₁ and initial wafer-showerhead gap WSG gap h₂ are indicated. In at least one implementation, prior to start of a process, initial WRG may be 200 microns, while initial WSG may be 25 mm. In at least one implementation, spindle 108 may be initially positioned 2 to 4 mm above its reference position. In at least one implementation, wafer chuck 104 may be positioned at its reference z-height.

FIG. 7B illustrates process tool 700 in a first process state, in accordance with at least one implementation. In at least one implementation, wafer chuck 104 is raised relative to its position shown in FIG. 7A to decrease WRG gap h₂. In at least one implementation, wafer chuck 104 may be raised 4 mm above its reference position, decreasing WRG gap h₂ to below 25 mm. In at least one implementation, WSG gap reduction may be in preparation for a subsequent deposition.

FIG. 7C illustrates a cross-sectional view of process tool 700 in a second process state, in accordance with at least one implementation. In at least one implementation, pedestal 122 may be raised to a higher position relative to its reference position, raising wafer chuck 104. In at least one implementation, WSG may be reduced between 5 mm and 10 mm. In at least one implementation, spindle 108 is raised relative to its reference position by same amount as pedestal 122. In at least one implementation, spindle 108 may be raised to approximately 24 mm above its reference position, lifting carrier ring 106 above wafer 112. In at least one implementation, by shifting spindle 108 by 24 mm, WRG gap h₁ can be increased to approximately 2 mm. In at least one implementation, such an increase in WRG gap h₁ may enable flow of layer growth inhibition vapors and gases to edge of wafer 112. In at least one implementation, WSG gap h₂ may be decreased by raising wafer chuck 104 close to showerhead 110. In at least one implementation, decrease of WSG (h₂) can enhance flow rate of layer growth inhibition vapors and gases to periphery of wafer 112 beyond that obtained by adjustment of WRG (h₁).

FIG. 7D illustrates a cross-sectional view of process tool 700 in a third process state, in accordance with at least one implementation. In at least one implementation, wafer chuck 104 is lowered by lowering pedestal 122 to approximately its initial position, increasing WSG. In at least one implementation, WSG gap h₂ may be greater than 25 mm. For example, h₂ may be 28 mm. In at least one implementation, spindle 108 may also be lowered to approximately 13 mm above its reference position, for example, increasing WRG gap h₁ to approximately 9 to 10 mm. In at least one implementation, WRG gap may be further increased to achieve a specified inhibitor gas flow rate, for example.

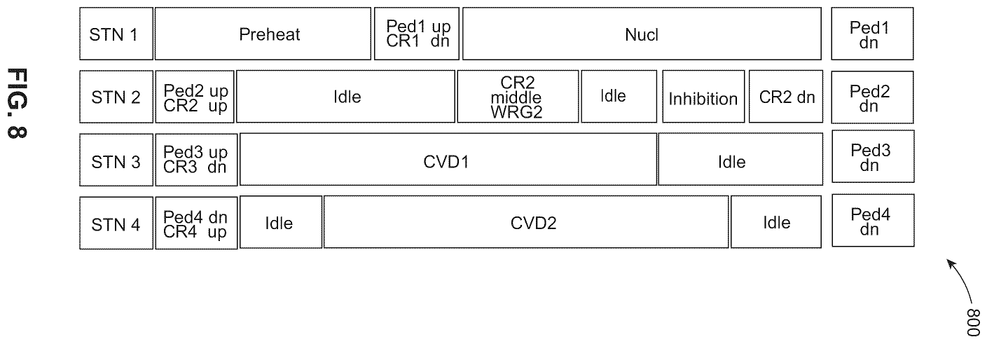

FIG. 8 illustrates an exemplary process flow chart 800 for a multi-station process tool carrying out parallel processes, in accordance with at least one implementation. In at least one implementation, process tool (e.g., process tool 600) may comprise four process stations (e.g., STN1-STN4). A single wafer is introduced into process chamber and transferred to STN1. In at least one implementation, STN2, STN3 and STN4 may also have wafers in process. In at least one implementation, all four processes may be run in parallel. In at least one implementation, at STN1, wafer is preheated to a process temperature, for example 330° C. In at least one implementation, wafer chuck (e.g., wafer chuck 104) may be at its initial operational position (z-height), as shown in FIG. 7A.

In at least one implementation, one carrier ring (CR) is shared between stations. In at least one implementation, a single carrier ring may be at each process station (e.g., STN1, STN2, STN3, and STN4). In at least one implementation, multiple carrier rings may be deployed at each station (e.g., CR1, CR2, CR3, and CR4).

In at least one implementation, a carrier ring (CR) may be initially parked at STN2 (e.g., CR2). In at least one implementation, after a preheating step, wafer pedestal at STN1 (PED1) is moved to a first process z-height to set WSG gap to a predetermined value (WSG1). An example of this procedure is shown in FIG. 7B, in accordance with at least one implementation. In at least one implementation, a nucleation step (Nucl) is carried out at STN1 following setting of WSG1 at STN1. In at least one implementation, during nucleation process at STN1, bulk CVD deposition may be carried out in parallel at STN3 and STN4 on wafers that have been transferred in succession to these stations. In at least one implementation, after nucleation step is complete at STN1, wafer chuck is moved up, reducing WSG1. An example of this procedure is shown in FIG. 7C, in accordance with at least one implementation.

In at least one implementation, at STN2, an inhibition process is in idle mode awaiting completion of film nucleation at STN1. In at least one implementation, after nucleation process is completed at STN1, wafer may be transferred to STN2. In at least one implementation, after wafer transfer to STN2, wafer chuck and carrier ring at STN2 (e.g., CR2) are moved to predetermined positions (e.g., WRG2 and WSG2, as shown in FIG. 8). In at least one implementation, setting of WRG2 and WSG2 may precede wafer-edge inhibition step.

Referring to STN2, in at least one implementation, spindle is moved to an intermediate position (spindle middle) to set WRG2 for wafer-edge inhibition step. In at least one implementation, during this stage, gases that inhibit layer growth may flow to wafer periphery under carrier ring overhang, reducing or preventing deposition at edge and backside of wafer. In at least one implementation, after inhibition step is complete, CR2 may be lowered to a level at or near its initial position (spindle down). In at least one implementation, CR2 may be placed directly on pedestal (e.g., WRG=0) by disengaging spindle from CR2.

In at least one implementation, STN3 and STN4 may be in an idle state during inhibition process at STN2 until inhibition process at STN2 is completed. In at least one implementation, a film deposition step on wafer may be performed at STN3, followed by a second (and final) film deposition process on wafer at STN4. In at least one implementation, film deposition steps at STN3 and STN4 are successive CVD processes. In at least one implementation, after completion of inhibition process at STN2, wafer may be transferred to STN3. In at least one implementation, once wafer is placed on pedestal at STN3 (e.g., PED3), PED3 may be moved up, decreasing WSG3. In at least one implementation, WRG3 is set to a minimal gap distance (e.g., 250 microns) by lowering carrier ring.

In at least one implementation, after completion of first film deposition process at STN3, wafer may be transferred to STN4. In at least one implementation, once wafer may be placed on pedestal at STN4 (PED4), PED4 may be moved down, increasing WSG4. In at least one implementation, CR4 may be lowered to a minimum z-height over wafer, minimizing WRG4. In at least one implementation, WRG4 may be between 250 microns and 1000 microns, enabling a flat edge profile of grown film. In at least one implementation, CR4 is moved up, increasing WRG4 to several millimeters. In at least one implementation, at STN4, CVD process is continued with a larger WRG, enabling a peaked film profile to develop at wafer edge.

In at least one implementation, for multiple wafers being processed simultaneously, wafer at STN4 may be transferred out of process chamber and wafer at STN3 may be transferred to STN4 for further processing (e.g., a second CVD step). In at least one implementation, wafer at STN2 may be transferred to STN3, whereas a nucleated wafer at STN1 is transferred to STN2 for growth inhibition treatment.

It is understood that different processes shown in FIG. 8 are exemplary, and that order and arrangement of different processes shown may be reshuffled. In at least one implementation, a CVD process may be performed at STN2 in advance and/or in succession to inhibition process. In at least one implementation, likewise, an inhibition process or nucleation process may be performed at any other station STN1, STN3, or STN4, and not limited to STN1 or STN2.

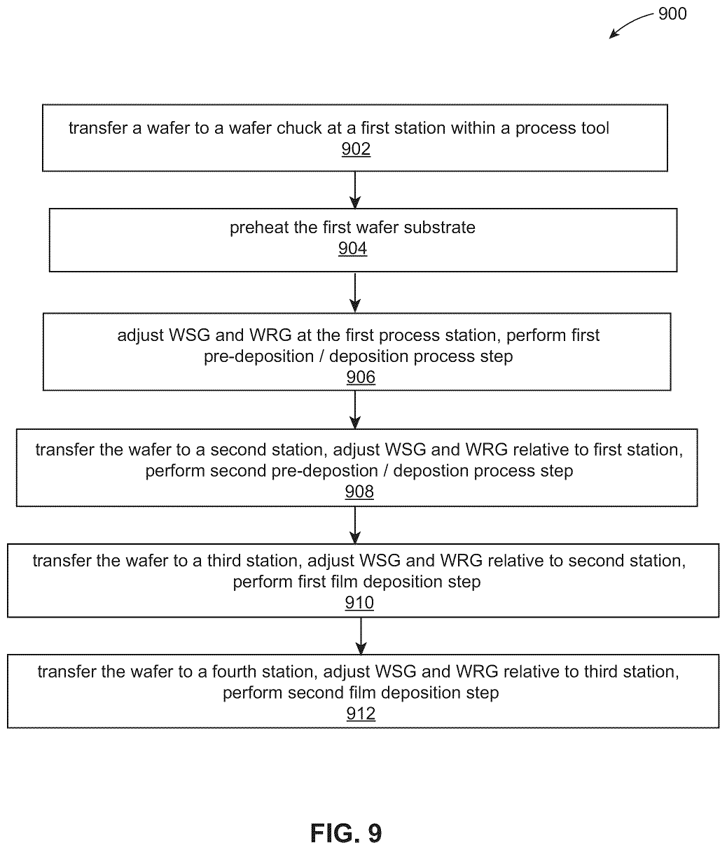

FIG. 9 illustrates an exemplary flow chart 900 for a method of operating a process chamber, in accordance with at least one implementation. In at least one implementation, method may be part of software to automatically command operations performed in a semiconductor fabrication tool, such as process tool 500. In at least one implementation, process chamber (e.g., vacuum chamber 102) comprises at least two process stations. In at least one implementation, process stations may be like process station 501 shown in FIG. 5. In at least one implementation, process chamber comprises four process stations. In at least one implementation, processes included in flow chart 900 may be like processes described in multi-station process flow chart 800.

Described below are operations that may be performed by execution by processor 506 of software-encoded process steps stored within memory 508, shown in FIG. 5. In at least one implementation, software-encoded process recipe steps can comprise code instructions for adjusting WRG and/or WSG spacings at one or more process stations (e.g., process station 501, FIG. 5) of a process tool uniquely for each process for which recipes may be stored in a process library.

Referring to FIG. 5, in at least one implementation, signals from output circuit 510 may send commands to motor 512 coupled to pedestal 122 as shown in FIG. 5. In at least one implementation, operations described below may comprise commanding motor 512 to change vertical position or z-height of wafer chuck 104 relative to a reference position of wafer chuck 104. In at least one implementation, likewise, for adjusting z-height of carrier ring 106 relative to a reference position of carrier ring 106, software stored in memory 508 may be executed by processor 506 to command spindle 108 via output circuit 510 (as shown in FIG. 5) to raise and lower carrier ring 106 with respect to a preset reference position of carrier ring 106.

At operation 902, according to at least one implementation, a wafer is transferred into process chamber to a process station (e.g., STN1). In at least one implementation, wafer may be transferred by a rotary indexer (e.g., rotary indexer 618, FIG. 6).

At operation 904, in at least one implementation, wafer at STN1 may undergo a preheat step In at least one implementation, temperature of wafer may be raised to over 300° C. In at least one implementation, wafers at other stations, such as STN2, may be similarly heated.

At operation 906, in at least one implementation, pedestal at STN1 (e.g., Ped1) may be actuated by a motor (e.g., motor 512) to raise wafer chuck (e.g., wafer chuck 104) to a first z-height in preparation for a nucleation process. In at least one implementation, z-height adjustment of PED1 sets WSG1 to a distance h₂ below showerhead (e.g., showerhead 110). In at least one implementation, WSG1 distance h₂ may be an optimal WSG corresponding to optimal nucleation process parameters, for example. In at least one implementation, during nucleation step, gases are distributed over wafer (e.g., wafer 112) by showerhead 110. In at least one implementation, WSG1 may be set at distance h₂ relative to WSG at a next station (STN2) such that nucleation process gases flow at a predetermined flux (e.g., molecules of process gas per second per cm²) over wafer. In at least one implementation, process gas flux may be greater as WSG is decreased. In at least one implementation, wafer-ring gap WRG1 may be set to a minimal value h₁ to shield wafer edge (e.g., edge 120) from exposure to nucleation gases. In at least one implementation, film growth at wafer edge and backside (e.g., wafer backside 126) may be mitigated by reduction of WRG1 to a minimal value (e.g., h₁ may be approximately 250 microns).

At operation 908, in at least one implementation, wafer at STN1 may be transferred to STN2 by rotary indexer. In at least one implementation, after positioning wafer on pedestal at STN2 (Ped2), wafer chuck is lowered to increase WSG2 to a larger h₂ relative to WSG1, in preparation for a film growth inhibition treatment process. In at least one implementation, spindle at STN2 (e.g., spindle 108) is commanded to move upward, raising carrier ring (e.g., CR2) at STN2 to increase WRG2 to a h₁ of several millimeters above wafer. In at least one implementation, increasing WRG2 enables flow of film growth inhibitor gases to flow to wafer edge and wafer backside. In at least one implementation, film growth inhibition treatment performed at STN2 may produce surface chemistry on wafer that suppresses undesired nucleation and film growth at wafer edge and backside during deposition of film precursors (e.g., CVD) at STN3 and STN4. In at least one implementation, an increase in WRG may direct flow of film growth inhibitor gases to wafer edge and backside rather than in central portion of wafer, where film growth is desired.

At operation 910, in at least one implementation, wafer is transferred to STN3 in preparation for a first film deposition step (e.g., CVD1). In at least one implementation, after wafer is positioned on pedestal at STN3 (Ped3), Ped3 may be raised to reduce WSG3 to a distance h₂ that is smaller than WSG2. In at least one implementation, reducing WSG may increase process gas flux over wafer. In at least one implementation, CVD1 is performed at STN3 to grow a film to a predetermined thickness. In at least one implementation, spindle at STN3 is adjusted such that WRG3 distance h₁ is minimal (e.g., 250 microns), shielding wafer edge and backside from large fluxes of precursor molecules. In at least one implementation, inhibition chemistry deposited on wafer edge and backside at STN2 mitigate undesired nucleation and growth of film material at these locations.

At operation 912, in at least one implementation, wafer is transferred to STN4 in preparation for a second film growth step (e.g., CVD2). In at least one implementation, pedestal at STN4 (Ped4) is lowered to increase WSG4. In at least one implementation, process gas flux over wafer may be reduced by increasing WSG gap distance h₂. In at least one implementation, spindle at STN4 is raised to increase WRG4 gap distance h₁ to several millimeters. In at least one implementation, increasing WRG4 enables some flow of film deposition precursors over wafer edge during CVD2. In at least one implementation, CVD2 may be limited in duration relative to CVD1 to permit limited growth of material below carrier ring at STN4 (CR4). In at least one implementation, a resulting film profile may exhibit a peak at or near wafer edge.

In at least one implementation, while flow chart 900 indicates a specific order to particular processes, it is understood that depiction is exemplary and that any suitable number, type and order of process steps may be employed.

Examples are provided in following paragraphs that illustrate at least one implementation. Here, examples can be combined with other examples. As such, at least one implementation can be combined with another implementation without changing scope of at least one implementation.

Example 1 is a process tool, comprising a wafer chuck a showerhead, wherein the wafer chuck is coupled to a motor that is operable to vertically displace the wafer chuck relative to the showerhead; and a carrier ring between the wafer chuck and the showerhead, wherein the carrier ring comprises an overhang that extends over an edge of the wafer, and wherein the carrier ring is mechanically coupled to a spindle operable to vertically displace the carrier ring relative to the wafer chuck.

Example 2 includes all features of example 1, wherein the motor is electrically coupled to a command module.

Example 3 includes all features of example 2, wherein the spindle is electrically coupled to the command module.

Example 4 includes all features of example 3, wherein the command module comprises a processor and a memory coupled to the processor, wherein the command module is electrically coupled to a human-machine interface.

Example 5 is a system, comprising a vacuum chamber; at least one process station within the vacuum chamber, the at least one process station comprising a wafer chuck a showerhead, wherein the wafer chuck is coupled to a motor that is operable to vertically displace the wafer chuck relative to the showerhead; and a carrier ring between the wafer chuck and the showerhead, wherein the carrier ring comprises an overhang that extends from an edge of the wafer, and wherein the carrier ring is mechanically coupled to a spindle operable to vertically displace the carrier ring relative to the wafer chuck a processor electrically coupled to the spindle and the motor; and a memory coupled to the processor, wherein the memory comprises binary code to command the spindle and the motor, wherein the binary code comprises multiple software instructions to adjust a first vertical height of the carrier ring relative to the wafer chuck and a second vertical height of the wafer chuck relative to the showerhead.

Example 6 includes all features of example 5, further comprising a process gas source coupled to the showerhead.

Example 7 includes all features of example 5, wherein one or more motion-control subroutines are stored in the memory, the one or more motion-control subroutines comprise the multiple software instructions, wherein the one or more motion-control subroutines are callable by at least one software-encoded process step, and wherein the at least one software-encoded process step is stored in the memory.

Example 8 includes all features of example 7, wherein the one or more motion-control subroutines are callable by a human-machine interface, wherein the human-machine interface is operable to call the one or more motion-control subroutines to move the carrier ring and to move the wafer chuck.

Example 9 includes all features of example 8, wherein the multiple software instructions further comprise instructions to control a flow rate of an inert or reactive process gas at an edge of the wafer chuck.

Example 10 includes all features of example 9, further comprising multiple process stations within the vacuum chamber.

Example 11 is a method for controlling a deposition process, comprising placing a wafer within a process tool, wherein the process tool comprises a wafer chuck, a showerhead, wherein the wafer chuck is coupled to a motor that is operable to vertically displace the wafer chuck relative to the showerhead; and a carrier ring between the wafer chuck and the showerhead, wherein the carrier ring comprises an overhang that extends from an edge of the wafer, and wherein the carrier ring is mechanically coupled to a spindle operable to vertically displace the carrier ring relative to the wafer chuck; adjusting a first gap distance between the carrier ring and the wafer chuck; and adjusting a second gap distance between the wafer chuck and the showerhead.

Example 12 includes all features of example 11, wherein adjusting the first gap distance between the carrier ring and the wafer chuck comprises commanding the spindle to change a first z-height of the carrier ring with respect to a first reference position of the spindle.

Example 13 includes all features of example 12, wherein adjusting the second gap distance between the wafer chuck and the showerhead comprises commanding the motor to change a second z-height of the wafer chuck with respect to a second reference position of the wafer chuck.

Example 14 includes all features of example 13, wherein the method further comprises increasing the first gap distance between the carrier ring and the wafer chuck and increasing the second gap distance between the wafer chuck and the showerhead.

Example 15 includes all features of example 14, wherein increasing the first gap distance between the carrier ring and the wafer chuck comprises commanding the spindle to change a first z-height of the carrier ring to a third z-height with respect to the first reference position of the spindle, wherein the third z-height is greater than the first z-height.

Example 16 includes all features of example 15, wherein increasing the second gap distance between the wafer chuck and the showerhead comprises commanding the motor to change a second z-height of the wafer chuck to a fourth z-height with respect to the second reference position of the wafer chuck, wherein the fourth z-height is greater than the second z-height.

Example 17 includes all features of example 16, wherein the method further comprises decreasing the first gap distance between the carrier ring and the wafer chuck and decreasing the second gap distance between the wafer chuck and the showerhead.

Example 18 includes all features of example 17, wherein decreasing the first gap distance between the carrier ring and the wafer chuck comprises commanding the spindle to change the first z-height of the carrier ring to a fifth z-height of the carrier ring with respect to the first reference position of the spindle, and wherein the fifth z-height is less than the first z-height.

Example 19 includes all features of example 18, wherein decreasing the second gap distance between the wafer chuck and the showerhead comprises commanding the motor to change the second z-height of the wafer chuck to a sixth z-height of the wafer chuck with respect to the second reference position of the wafer chuck, and wherein the sixth z-height is greater than the second z-height.

Example 20 is a method for controlling a process, comprising transferring a first wafer to a first process station of a plurality of process stations within a process tool, wherein individual ones of the plurality of process stations comprise a wafer chuck a showerhead, wherein the wafer chuck is coupled to a motor that is operable to vertically displace the wafer chuck relative to the showerhead; and a carrier ring between the wafer chuck and the showerhead, wherein the carrier ring comprises an overhang that extends from an edge of the wafer, and wherein the carrier ring is mechanically coupled to a spindle operable to vertically displace the carrier ring relative to the wafer chuck; and transferring a second wafer to a second process station of the plurality of process stations.

Example 21 includes all features of example 20, further comprising preheating the first wafer adjusting a first gap to a first initial position between a first carrier ring and the first wafer adjusting a second gap to a second initial position between the first wafer and a first showerhead adjusting a third gap to a third initial position between a second carrier ring and the second wafer adjusting a fourth gap to a fourth initial position between the second wafer and a second showerhead; and depositing a nucleation layer on the first wafer.

Example 22 includes all features of example 21, further comprising raising a first wafer chuck to an idle position to decrease the second gap between the first wafer and the first showerhead raising a second wafer chuck to a first operational position, to decrease the fourth gap between the second wafer and the second showerhead raising the carrier ring to a second operational position, to increase the third gap between the carrier ring and the second wafer flowing a process gas from the second showerhead; and lowering the carrier ring to return the carrier ring to the first operational position.

Besides what is described herein, various modifications may be made to at least one implementation thereof without departing from its scope. Therefore, illustrations of at least one implementation herein should be construed as examples, and not restrictive to scope of at least one implementation.

1. A process tool, comprising:
a wafer chuck;
a showerhead, wherein the wafer chuck is coupled to a motor that is operable to vertically displace the wafer chuck relative to the showerhead; and
a carrier ring between the wafer chuck and the showerhead, wherein the carrier ring comprises an overhang that extends over an edge of a wafer on the wafer chuck, and wherein the carrier ring is mechanically coupled to a spindle operable to vertically displace the carrier ring relative to the wafer chuck.

2. The process tool of claim 1, wherein the motor is electrically coupled to a command module.

3. The process tool of claim 2, wherein the spindle is electrically coupled to the command module.

4. The process tool of claim 3, wherein the command module comprises a processor and a memory coupled to the processor, wherein the command module is electrically coupled to a human-machine interface.

5. A system, comprising:
a vacuum chamber; and
at least one process station within the vacuum chamber, the at least one process station comprising:
a wafer chuck;
a showerhead, wherein the wafer chuck is coupled to a motor that is operable to vertically displace the wafer chuck relative to the showerhead; and
a carrier ring between the wafer chuck and the showerhead, wherein the carrier ring comprises an overhang that extends over an edge of a wafer on the wafer chuck, and wherein the carrier ring is mechanically coupled to a spindle operable to vertically displace the carrier ring relative to the wafer chuck, wherein the system further comprises:
a processor electrically coupled to the spindle and the motor; and
a memory coupled to the processor, wherein the memory comprises binary code to command the spindle and the motor, wherein the binary code comprises multiple software instructions to adjust a first vertical height of the carrier ring relative to the wafer chuck and a second vertical height of the wafer chuck relative to the showerhead.

6. The system of claim 5, further comprising a process gas source coupled to the showerhead.

7. The system of claim 5, wherein one or more motion-control subroutines are stored in the memory, the one or more motion-control subroutines comprise the multiple software instructions, wherein the one or more motion-control subroutines are callable by at least one software-encoded process step, and wherein the at least one software-encoded process step is stored in the memory.

8. The system of claim 7, wherein the one or more motion-control subroutines are callable by a human-machine interface, wherein the human-machine interface is operable to call the one or more motion-control subroutines to move the carrier ring and to move the wafer chuck.

9. The system of claim 8, wherein the multiple software instructions further comprise instructions to control a flow rate of an inert or reactive process gas at an edge of the wafer chuck.

10. The system of claim 9, further comprising multiple process stations within the vacuum chamber.

11. A method for controlling a deposition process, the method comprising:
placing a wafer within a process tool, wherein the process tool comprises:
a wafer chuck;
a showerhead, wherein the wafer chuck is coupled to a motor that is operable to vertically displace the wafer chuck relative to the showerhead; and
a carrier ring between the wafer chuck and the showerhead, wherein the carrier ring comprises an overhang that extends over an edge of the wafer, and
wherein the carrier ring is mechanically coupled to a spindle operable to vertically displace the carrier ring relative to the wafer chuck, wherein the method further comprises:
adjusting a first gap distance between the carrier ring and the wafer chuck; and
adjusting a second gap distance between the wafer chuck and the showerhead.

12. The method of claim 11, wherein adjusting the first gap distance between the carrier ring and the wafer chuck comprises commanding the spindle to change a first z-height of the carrier ring with respect to a first reference position of the spindle.

13. The method of claim 12, wherein adjusting the second gap distance between the wafer chuck and the showerhead comprises commanding the motor to change a second z-height of the wafer chuck with respect to a second reference position of the wafer chuck.

14. The method of claim 13, wherein the method further comprises increasing the first gap distance between the carrier ring and the wafer chuck and increasing the second gap distance between the wafer chuck and the showerhead.

15. The method of claim 14, wherein increasing the first gap distance between the carrier ring and the wafer chuck comprises commanding the spindle to change the first z-height of the carrier ring to a third z-height with respect to the first reference position of the spindle, wherein the third z-height is greater than the first z-height.

16. The method of claim 15, wherein increasing the second gap distance between the wafer chuck and the showerhead comprises commanding the motor to change the second z-height of the wafer chuck to a fourth z-height with respect to the second reference position of the wafer chuck, wherein the fourth z-height is greater than the second z-height.

17. The method of claim 16, wherein the method further comprises decreasing the first gap distance between the carrier ring and the wafer chuck and decreasing the second gap distance between the wafer chuck and the showerhead.

18. The method of claim 17, wherein decreasing the first gap distance between the carrier ring and the wafer chuck comprises commanding the spindle to change the first z-height of the carrier ring to a fifth z-height of the carrier ring with respect to the first reference position of the spindle, and wherein the fifth z-height is less than the first z-height.

19. The method of claim 18, wherein decreasing the second gap distance between the wafer chuck and the showerhead comprises commanding the motor to change the second z-height of the wafer chuck to a sixth z-height of the wafer chuck with respect to the second reference position of the wafer chuck, and wherein the sixth z-height is greater than the second z-height.

20. A method for controlling a process, comprising:
transferring a first wafer to a first process station of a plurality of process stations within a process tool, wherein individual ones of the plurality of process stations comprise:
a wafer chuck;
a showerhead, wherein the wafer chuck is coupled to a motor that is operable to vertically displace the wafer chuck relative to the showerhead; and
a carrier ring between the wafer chuck and the showerhead, wherein the carrier ring comprises an overhang that extends over an edge of a wafer on the wafer chuck, and wherein the carrier ring is mechanically coupled to a spindle operable to vertically displace the carrier ring relative to the wafer chuck, wherein the method further comprises:
transferring a second wafer to a second process station of the plurality of process stations.

21. The method of claim 20, further comprising:
preheating the first wafer;
adjusting a first gap to a first initial position between a first carrier ring and the first wafer;
adjusting a second gap to a second initial position between the first wafer and a first showerhead;
adjusting a third gap to a third initial position between a second carrier ring and the second wafer;
adjusting a fourth gap to a fourth initial position between the second wafer and a second showerhead; and
depositing a nucleation layer on the first wafer.

22. The method of claim 21, further comprising:
raising a first wafer chuck to an idle position to decrease the second gap between the first wafer and the first showerhead;
raising a second wafer chuck to a first operational position, to decrease the fourth gap between the second wafer and the second showerhead;
raising the carrier ring to a second operational position, to increase the third gap between the carrier ring and the second wafer;
flowing a process gas from the second showerhead; and
lowering the carrier ring to return the carrier ring to the first operational position.
